(19) United States
(12) Patent Application Publication
(10) Pub. No.: US 2015/0190982 A1
(43) Pub. Date: Jul. 9, 2015

(54) GRAPHITE COMPOSITE MATERIAL

(71) Applicant: KANEKA CORPORATION, Osaka-shi, Osaka (JP)

(72) Inventors: Makoto Kutsumizu, Settsu-shi (JP); Yasushi Nishikawa, Settsu-shi (JP); Yusuke Ohta, Settsu-shi (JP); Satoshi Katayama, Settsu-shi (JP); Takashi Inada, Settsu-shi (JP); Motoaki Kobayashi, Settsu-shi (JP)

(73) Assignee: KANEKA CORPORATION, Osaka-shi, Osaka (JP)

(21) Appl. No.: 14/413,734

(22) PCT Filed: Jul. 12, 2013
(86) PCT No.: PCT/JP2013/004318

§ 371 Date: Jan. 9, 2015

(30) Foreign Application Priority Data
Jul. 19, 2012 (JP) 2012-160742

(51) Int. Cl. B32B 7/04; B32B 9/04; B32B 3/26; B32B 9/00; C01B 31/04; H05K 1/02

(52) U.S. Cl. CPC B32B 7/04; C01B 31/0423; H05K 1/0203; B32B 3/266; B32B 9/007; B32B 9/045; B32B 2250/40; B32B 2250/03; B32B 2307/302; B32B 2313/04; B32B 2457/08

(57) ABSTRACT

Disclosed herein is a graphite composite material including a graphite film and a resin layer, wherein peeling-off of the resin layer from the graphite film is suppressed. The graphite composite material includes: a graphite film; and a resin layer formed on at least one surface of the graphite film, wherein the graphite film has through holes, wherein a number of the through is 100 to 1000 per cm², and the through holes have a diameter of 0.10 mm or more but 1.00 mm or less, and wherein part of the resin layer is formed also in the through holes.

### TECHNICAL FIELD

The present invention relates to a graphite composite material including a resin layer and a graphite film layer.

### BACKGROUND ART

Graphite film has high heat dissipation properties due to its high heat conductivity, but tends to be poor in adhesion to resin or other materials due to its low surface activity. For example, when used as a heat dissipation material for circuit boards (Patent Document 1), a graphite film needs to be combined with a resin. However, when a resin layer is directly formed on the surface of a graphite film, the resulting graphite composite material has low mechanical strength due to low interlaminar strength between the graphite film and the resin layer. Particularly, in the case of a structure, such as a circuit board having a metal layer, in which volatile matter in materials is less likely to be discharged to the outside of a system, there is a case where, due to the low interlaminar strength between the graphite film and the resin layer, delamination is caused between the graphite film and the resin layer by the expansion of volatile matter released from resin under high temperature conditions in a soldering process or the like.

### PRIOR ART DOCUMENTS

### Patent Documents

Patent Document 1: JP-A-2010-80572

### DISCLOSURE OF THE INVENTION

### Problems to be Solved by the Invention

It is an object of the present invention to provide a graphite composite material including a graphite film and a resin layer, wherein delamination between the resin layer and the graphite film is suppressed.

### Means for Solving the Problems

The present invention is directed to a graphite composite material comprising: a graphite film; and a resin layer formed on at least one surface of the graphite film, wherein the graphite film has through holes, wherein the number of the through holes is 100 to 1000 per cm², and the through holes have a diameter of 0.10 mm or more but 1.00 mm or less, and wherein part of the resin layer is formed also in the through holes.

It is preferred that the graphite composite material has an interlaminar strength of 0.15 N/mm or more.

It is also preferred that a distance between outer diameters of the through holes is 0.80 mm or less.

It is also preferred that the graphite film has been subjected to at least one film surface treatment selected from the group consisting of corona treatment, flame treatment, ultraviolet treatment, alkali treatment, primer treatment, sandblast treatment, and plasma treatment.

The present invention is also directed to a circuit board comprising the graphite composite material described above.

### Effects of the invention

According to the present invention, it is possible to provide a graphite composite material including a graphite film and a resin layer, wherein delamination between the resin layer and the graphite film is suppressed.

### BRIEF DESCRIPTION OF THE DRAWINGS

FIG. 1 is a top view of a through hole in the present invention.

FIG. 2 is a top view showing the arrangement of through holes in the present invention.

FIG. 3 is a view showing the structure of a sample for peel test in the present invention.

FIG. 4 is a view showing the structure of a sample of Example 1 of the present invention.

FIG. 5 is a view showing the structure of a sample of Example 14 of the present invention.

### PREFERRED MODE FOR CARRYING OUT THE INVENTION

A graphite composite material according to the present invention includes: a graphite film; and a resin layer formed on at least one surface of the graphite film, wherein the graphite film has through holes, wherein the number of the through holes is 100 to 1000 per cm², and the through holes have a diameter of 0.10 mm or more but 1.00 mm or less, and wherein part of the resin layer is formed also in the through holes.

The graphite film used in the present invention has a plurality of through holes formed in its thickness direction. Providing through holes in the graphite film makes it possible to form the resin layer in the through holes. This makes it possible to prevent the resin layer formed on the surface of the graphite film from peeling off from the surface of the graphite film.

The number of the through holes of the graphite film used in the present invention is 100 to 1000 per cm² (area of the graphite film). The number of the through holes formed in the graphite film is preferably 100 per cm², more preferably 150 per cm², even more preferably 200 per cm², most preferably 300 per cm² or more. When the number of the through holes formed in the graphite film is 100 per cm² or more, there is an advantage that delamination between the graphite film and the resin layer formed on the surface of the graphite film is suppressed. The number of the through holes formed in the graphite film is preferably 1000 per cm² or less, more preferably 800 per cm² or less, even more preferably 600 per cm² or less. When the number of the through holes formed in the graphite film is 1000 per cm² or less, there is an advantage that a more homogeneous temperature distribution is achieved and local temperature elevation can be suppressed.

The through holes of the graphite film used in the present invention have a diameter of 0.10 mm or more but 1.00 mm or less. The diameter of the through holes formed in the graphite film is preferably 0.10 mm or more, more preferably 0.15 mm or more, even more preferably 0.20 mm or more. When the diameter of the through holes formed in the graphite film is 0.10 mm or more, the resin layer formed in the through holes is sufficiently large, and is therefore less likely to be pulled out of the through holes. Therefore, even when the resin layer on the surface of the graphite film is pulled, delamination can be suppressed by the resin layer in the through holes. The diameter of the through holes formed in the graphite film is preferably 1.00 mm or less, more preferably 0.80 mm or less, even more preferably 0.60 mm or less. When the diameter of the through holes formed in the graphite film is 1.00 mm or less, there is an advantage that a more homogeneous temperature distribution is achieved and local temperature elevation can be suppressed.

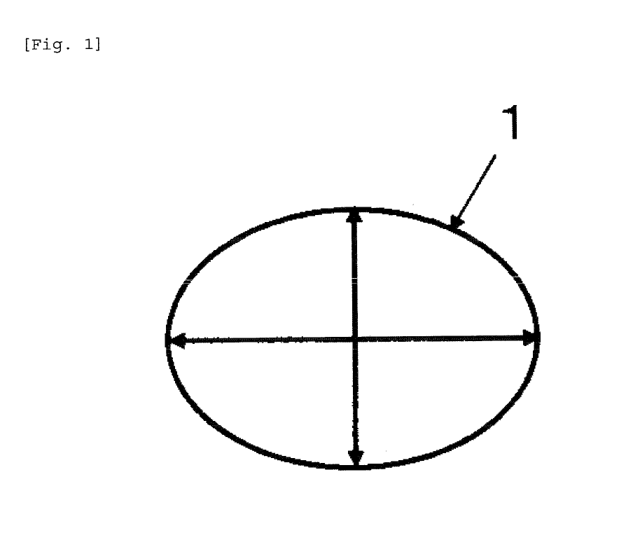

Here, referring to FIG. 1, the diameter of the through holes refers to the average of the length of a line segment on a straight line passing through the center of a through hole 1 and the outermost edge of the through hole 1 and the length of a line segment on a straight line orthogonal to that straight line. In the graphite composite material according to the present invention, the resin layer is formed on at least one surface of the graphite film.

The resin layer is not particularly limited. However, when the graphite composite material according to the present invention is used as a circuit board requiring a soldering process, an epoxy resin, phenol resin, or polyimide resin having heat resistance withstanding a temperature of, for example, 260° C. or more is preferably selected. Further, a resin that is less likely to release volatile matter at its use temperature is preferably selected, because there is a case where delamination is caused by volatile matter released from resin at high temperature in a soldering process or the like.

Further, a method for forming the resin layer is not particularly limited as long as the resin layer can be formed also in the through holes formed in the graphite film. For example, the resin layer can be formed on the surface of the graphite film and in the through holes by placing a prepreg sheet made of a semi-cured resin on a graphite film, preheating them to a temperature at which the resin is softened, and heating them under pressure using a hot press or an autoclave. Alternatively, a graphite film onto which a liquid resin has been applied may be pressed in a roll press. In the present invention, part of the resin layer is formed also in the through holes of the graphite film. Providing part of the resin layer, formed on the surface of the graphite film, also in the through holes makes it possible to suppress peeling-off of the resin layer, formed on the surface of the graphite film, from the graphite film. When the resin layers are formed on both surfaces of the graphite film, peeling-off of the resin layer can be more suppressed as compared to when the resin layer is formed on one surface of the graphite film.

The interlaminar strength (peel strength) of the graphite composite material according to the present invention is not particularly limited as long as the objects of the present invention can be achieved. However, the interlaminar strength between the graphite film and the resin layer formed on the surface of the graphite film is preferably 0.15 N/mm or more, more preferably 0.20 N/mm or more, even more preferably 0.30 N/mm or more. When the interlaminar strength between the graphite film and the resin layer formed on the surface of the graphite film is 0.15 N/mm or more, there is an advantage that delamination between the graphite film and the resin layer formed on the surface of the graphite film is suppressed.

The distance between the outer diameters of the through holes of the graphite composite material according to the present invention is not particularly limited as long as the objects of the present invention can be achieved. However, the distance between the outer diameters of the through holes formed in the graphite film is preferably 0.80 mm or less, more preferably 0.60 mm or less, even more preferably 0.50 mm or less, most preferably 0.40 mm or less. When the distance between the outer diameters of the through holes is 0.40 mm or less, there is an advantage that delamination between the graphite film and the resin layer formed on the surface of the graphite film is suppressed.

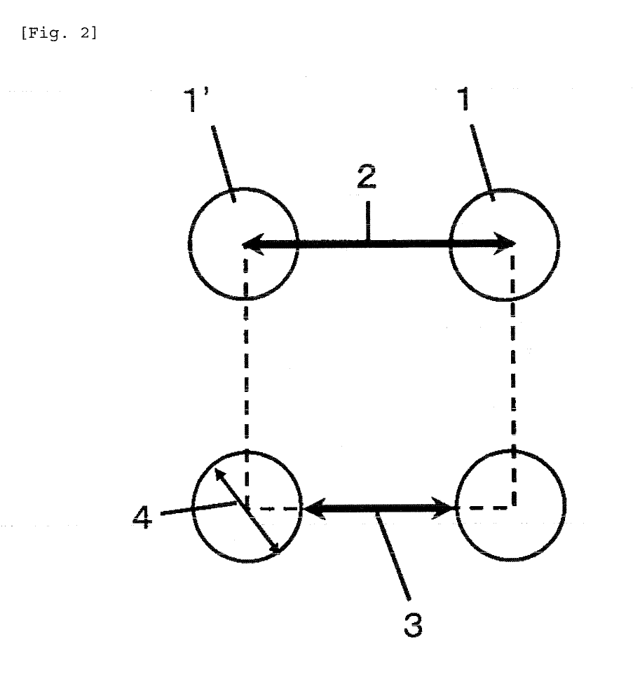

Here, referring to FIG. 2, the distance between the outer diameters of the through holes refers to a distance 3 between the outer diameter of a certain through hole 1 and the outer diameter of an adjacent through hole 1′ (through hole located nearest the certain through hole 1). For example, when a through hole outer diameter (through hole diameter) 4 is 50 μm and a pitch 2 between the through holes is 100 μm, the distance 3 between the outer diameters of the through holes is 50 μm. It is to be noted that in FIG. 2, all the through holes have the same through hole outer diameter.

The rate of hole area of the graphite film of the graphite composite material according to the present invention is not particularly limited as long as the objects of the present invention can be achieved. However, the rate of hole area of the graphite film is preferably 40% or less, more preferably 20% or less, even more preferably 10% or less. The rate of hole area of the graphite film is 40% or less, high heat dissipation properties can be maintained.

The graphite film used in the graphite composite material according to the present invention is not particularly limited as long as the objects of the present invention can be achieved. However, it is preferred that the graphite film has been subjected to at least one film surface treatment selected from the group consisting of corona treatment, flame treatment, ultraviolet treatment, alkali treatment, primer treatment, sandblast treatment, and plasma treatment. Such surface treatment can cover the shortage of the interlaminar strength between the resin layer and part of the graphite film where the through holes are not formed. That is, major delamination can be suppressed by the resin in the though holes, and minor delamination that occurs in areas between the through holes can be suppressed by the surface treatment.

A circuit board including the graphite composite material according to the present invention is excellent in heat conductivity, and therefore can be suitably used as a heat-dissipation circuit board. Examples of the heat-dissipation circuit board include circuit boards required to dissipate more heat such as embedded printed wiring boards and circuit boards for LEDs. Further, the graphite composite material according to the present invention is excellent in heat conductivity, and therefore can be used for all purposes relating to heat. For example, the graphite composite material according to the present invention can be used not only for circuit boards but also for power semiconductor devices.

The graphite film used in the present invention is not particularly limited, and may be one obtained by thermally treating a polymer film or one obtained by expanding natural graphite as a raw material. A graphite film obtained by thermally treating a polymer has high heat dissipation properties but is difficult to combine with other materials, because it has an excellent crystalline structure of graphite and therefore has low surface activity. However, according to the present invention, it is possible to obtain a graphite composite material excellent in both heat dissipation properties and surface activity from such a graphite film obtained by thermally treating a polymer.

A first method for producing the graphite film used in the present invention is one in which natural graphite as a raw material is expanded to obtain a graphite film. Specifically, graphite is immersed in an acid such as sulfuric acid to form a graphite intercalation compound, and then the graphite intercalation compound is expanded by heat treatment to exfoliate graphite into layers. After the exfoliation, the resulting graphite powder is washed to remove the acid, and a thin layer of the graphite powder is obtained. The graphite powder obtained in this way is further subjected to roll forming to obtain a graphite film.

A second method for producing the graphite film preferably used to achieve the objects of the present invention is one in which a polymer film made of a polyimide resin or the like is thermally treated to produce a graphite film.

In order to obtain a graphite film from a polymer film, first, a polymer film as a starting material is carbonized by preheat treatment to a temperature of about 1000° C. under a reduced pressure or an inert gas atmosphere to obtain a carbonized film. Then, the carbonized film is graphitized by heat treatment to a temperature of 2800° C. or higher under an inert gas atmosphere to form an excellent crystalline structure of graphite. In this way, a graphite film excellent in heat conductivity can be obtained. The graphite film produced by the second production method hardly absorbs water and therefore can be suitably used in circuit boards and the like. This is because even when used in circuit boards and the like, the graphite film produced by the second production method releases no volatile matter even under high-temperature conditions in a soldering process or the like, and is therefore less likely to peel off from resin.

(Uses)

The graphite composite material according to the present invention is excellent in heat conductivity, and therefore can be used for all purposes relating to heat. For example, the graphite composite material according to the present invention can be used for circuit boards, such as embedded printed wiring boards and circuit boards for LEDs, power semiconductor devices, and the like.

### EXAMPLES

(Graphite Film)

A polyamide acid solution (18.5 wt %) was obtained by dissolving 1 equivalent of pyromellitic dianhydride in a DMF (dimethyl formamide) solution in which 1 equivalent of 4,4′-oxydianiline was dissolved. An imidization catalyst containing DMF and 1 equivalent of acetic anhydride and 1 equivalent of isoquinoline with respect to carboxylic groups contained in polyamide acid was added to the solution for defoaming while the solution was cooled. Then, the mixed solution was applied onto an aluminum foil so that a mixed solution layer had a predetermined thickness after drying (75 μm). The mixed solution layer on the aluminum foil was dried using a hot air oven and a far-infrared heater. In this way, a polyimide film having a thickness of 75 μm was prepared.

The thus prepared polyimide film was sandwiched between graphite plates and subjected to carbonization treatment by heating in an electric furnace to 1400° C. at a temperature rise rate of 1° C./min. The carbonized film obtained by carbonization treatment was sandwiched between graphite plates and subjected to graphitization treatment by heating in a graphitization furnace to 2900° C. at a temperature rise rate of 1° C./min, and was then subjected to compression processing at a pressure of 20 MPa by single-plate press to obtain a graphite film (thickness: 40 μm). In the following Examples and Comparative Examples, this graphite film was used.

(Evaluations)

<Interlaminar Strength>

1. Resistance to Soldering Heat

The evaluation of interlaminar strength between a graphite film and a resin layer was performed by evaluating resistance to soldering heat in the following manner. The interlaminar strength was evaluated by performing a test for resistance to soldering heat. This is because in the test for resistance to soldering heat, delamination occurs in an area where the interlaminar strength is low due to the expansion of volatile matter released from resin.

A graphite composite material was cut into a 50 mm×50 mm test piece and immersed in a solder bath at 260° C. for 10 seconds to evaluate the interlaminar strength. In Examples 1 to 13 and Comparative Examples 1 to 4, after the immersion in a solder bath, a copper foil on the surface of the test piece was etched with an ammonium sulfate solution, and then the test piece was visually observed to evaluate the interlaminar strength. In Examples 14 to 18 and Comparative Example 5, after the immersion in a solder bath, the test piece was directly visually observed to evaluate the interlaminar strength.

The interlaminar strength was evaluated according to the following criteria: (A) the ratio of the area of a region(s) where delamination or void formation occurred between the resin layer and the graphite film to the total area of the graphite composite material was less than 1.0%; (B) the ratio was 1.0% or more but less than 10%; (C) the ratio was 10% or more but less than 25%; (D) the ratio was 25% or more but less than 50%; and (E) the ratio was 50% or more.

2. Peel Strength

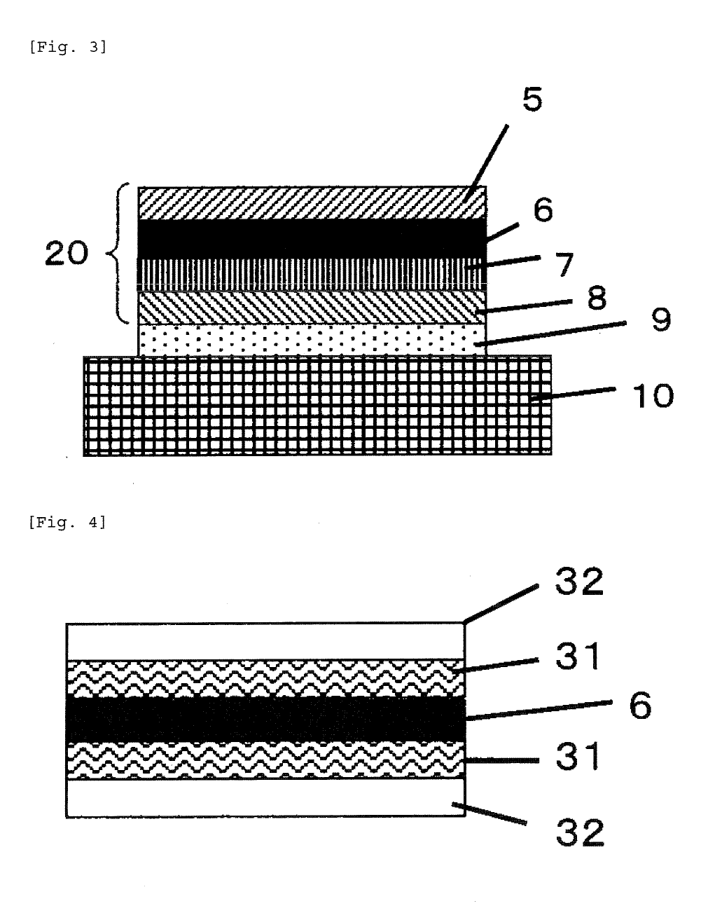

Referring to FIG. 3, a double-sided tape 9 (707 manufactured by Teraoka Seisakusho co, Ltd.) was bonded to one surface of a graphite composite material 20 with the use of a laminating machine, and then the graphite composite material 20 was bonded to an ABS plate 10 via the double-sided tape 9. Then, the graphite composite material 20 and the double-sided tape 9 were cut to have a width of 15 mm, a coverlay 6 was slightly peeled off from a graphite film 6, the end of the peeled coverlay 6 was pinched with a chuck of a peel strength tester, and then a peel test was performed at an angle of 90° and a peel rate of 100 mm/sec. Peel strength was determined by dividing the average of measured values at positions 10 mm to 60 mm away from the starting position of the test by a sample width of 15 mm. It is to be noted that the coverlay 6 corresponds to the resin layer in the present invention.

### Example 1

Through holes were formed by cutting out circles in the graphite film (thickness: 40 μm) with Laser Marker MD-T1010 manufactured by KEYENCE CORPORATION at a laser wavelength of 532 nm, a laser power of 80%, a frequency of 50 kHz, and a rate of 50 mm/min. Then, graphite powder created by laser processing was removed in an ultrasonic bath. The through holes had a diameter of 0.10 mm, and the pitch between the through holes was 0.70 mm (Number of through holes: 204 per cm², Distance between outer diameters of through holes: 0.60 mm, Rate of hole area: 1.6%). Then, as shown in FIG. 4, glass-epoxy prepregs 31 (R1661 (100 μm) manufactured by Panasonic Corporation, corresponding to the resin layers in the present invention) were stacked on both surfaces of the graphite film 6, and rolled copper foils 32 (35 μm) were further stacked on the outside of the glass-epoxy prepregs 31 to obtain a layered structure. Then, this layered structure was hot-pressed to produce a graphite composite material. The hot pressing was performed in the following manner to cure the epoxy resin: buffer materials were placed on both surfaces of the layered structure, and the layered structure was preheated at 100° C. and 1.0 MPa for 10 minutes and then heated to 170° C. and maintained at 170° C. and 3.4 MPa for 1 hour. In this way, a graphite composite material in which a resin layer was formed also in the through holes was produced. The results are shown in Table 1.

### Example 2

A graphite composite material was produced in the same manner as in Example 1 except that the through holes formed in the graphite film had a diameter of 0.15 mm, and the pitch between the through holes was 0.70 mm (Number of through holes: 204 per cm², Distance between outer diameters of through holes: 0.55 mm, Rate of hole area: 3.6%). The results are shown in Table 1.

### Example 3

A graphite composite material was produced in the same manner as in Example 1 except that the through holes formed in the graphite film had a diameter of 0.20 mm, and the pitch between the through holes was 0.70 mm (Number of through holes: 204 per cm², Distance between outer diameters of through holes: 0.50 mm, Rate of hole area: 6.4%). The results are shown in Table 1.

### Example 4

A graphite composite material was produced in the same manner as in Example 1 except that the through holes formed in the graphite film had a diameter of 0.25 mm, and the pitch between the through holes was 0.70 mm (Number of through holes: 204 per cm², Distance between outer diameters of through holes: 0.45 mm, Rate of hole area: 10.0%). The results are shown in Table 1.

### Comparative Example 1

A graphite composite material was produced in the same manner as in Example 1 except that through holes were not formed in the graphite film. The results are shown in Table 1.

### Comparative Example 2

A graphite composite material was produced in the same manner as in Example 1 except that the through holes formed in the graphite film had a diameter of 0.05 mm, and the pitch between the through holes was 0.70 mm (Number of through holes: 204 per cm², Distance between outer diameters of through holes: 0.65 mm, Rate of hole area: 0.4%). The results are shown in Table 1.

TABLE 1

| | | GS | | | | | | | |
|---|---|---|---|---|---|---|---|---|---|
| | | | | Pitch | | Distance | | | |
| | | | Through | between | Number of | between outer | Rate of | | Interlaminar |
| | | Thick- | hole | through | through | diameters of | hole | | strength |
| | | ness | diameter | holes | holes | through holes | area | Corona | (Resistance to |
| | Structure | μm | mm | mm | per cm² | mm | % | treatment | soldering heat) |
| Example 1 | Copper foil/ | 40 | 0.10 | 0.70 | 204 | 0.60 | 1.6 | Not done | D |
| | Glass-epoxy/GS/ | | | | | | | | |
| | Glass-epoxy/ | | | | | | | | |
| | Copper foil | | | | | | | | |
| Example 2 | Copper foil/ | 40 | 0.15 | 0.70 | 204 | 0.55 | 3.6 | Not done | C |
| | Glass-epoxy/GS/ | | | | | | | | |
| | Glass-epoxy/ | | | | | | | | |
| | Copper foil | | | | | | | | |
| Example 3 | Copper foil/ | 40 | 0.20 | 0.70 | 204 | 0.50 | 6.4 | Not done | B |
| | Glass-epoxy/GS/ | | | | | | | | |
| | Glass-epoxy/ | | | | | | | | |
| | Copper foil | | | | | | | | |
| Example 4 | Copper foil/ | 40 | 0.25 | 0.70 | 204 | 0.45 | 10.0 | Not done | B |
| | Glass-epoxy/GS/ | | | | | | | | |
| | Glass-epoxy/ | | | | | | | | |
| | Copper foil | | | | | | | | |
| Comparative | Copper foil/ | 40 | — | — | 0 | — | 0.0 | Not done | E |
| Example 1 | Glass-epoxy/GS/ | | | | | | | | |
| | Glass-epoxy/ | | | | | | | | |
| | Copper foil | | | | | | | | |
| Comparative | Copper foil/ | 40 | 0.05 | 0.70 | 204 | 0.65 | 0.4 | Not done | E |
| Example 2 | Glass-epoxy/GS/ | | | | | | | | |
| | Glass-epoxy/ | | | | | | | | |
| | Copper foil | | | | | | | | |

As shown in Table 1, comparisons were made under conditions where the number of through holes was 204 per cm². As can be seen from the results shown in Table 1, in the case of Comparative Example 1 in which through holes were not formed in the graphite film, delamination occurred between the graphite film and the epoxy resin layer in the test for resistance to soldering heat so that the epoxy resin layer was completely peeled off from the graphite film. Further, also in the case of Comparative Example 2 in which through holes were formed but had a diameter as small as 0.05 mm, significant delamination occurred. On the other hand, in the cases of Examples 1 to 4, delamination was suppressed by allowing the through holes to have a diameter as large as 0.10 mm or more. That is, when the through hole diameter was too small such as 0.05 mm, the resin layer could not withstand the expansion of volatile matter released from resin at a high temperature such as 260° C., and therefore peeling-off of the resin layer formed on the surface of the graphite film could not be suppressed. This is because, when the through hole diameter is too small such as 0.05 mm, the resin layer formed in the through holes is not sufficiently large and is therefore easily pulled out of the through holes.

Further, as can be seen from a comparison among Examples 1 to 4, delamination is suppressed when the through hole diameter is 0.10 mm or more, and further, the effect of suppressing delamination is higher when the through hole diameter is larger, and is much higher when the through hole diameter is 0.20 mm or more.

### Example 5

A graphite composite material was produced in the same manner as in Example 1 except that the through holes formed in the graphite film had a diameter of 0.15 mm, and the pitch between the through holes was 0.75 mm (Number of through holes: 178 per cm², Distance between outer diameters of through holes: 0.60 mm, Rate of hole area: 3.1%). The results are shown in Table 2.

### Example 6

A graphite composite material was produced in the same manner as in Example 1 except that the through holes formed in the graphite film had a diameter of 0.20 mm, and the pitch between the through holes was 0.80 mm (Number of through holes: 156 per cm², Distance between outer diameters of through holes: 0.60 mm, Rate of hole area: 4.9%). The results are shown in Table 2.

### Example 7

A graphite composite material was produced in the same manner as in Example 1 except that the through holes formed in the graphite film had a diameter of 0.25 mm, and the pitch between the through holes was 0.85 mm (Number of through holes: 138 per cm², Distance between outer diameters of through holes: 0.60 mm, Rate of hole area: 6.8%). The results are shown in Table 2.

### Comparative Example 3

A graphite composite material was produced in the same manner as in Example 1 except that the through holes formed in the graphite film had a diameter of 0.05 mm, and the pitch between the through holes was 0.65 mm (Number of through holes: 237 per cm², Distance between outer diameters of through holes: 0.60 mm, Rate of hole area: 0.5%). The results are shown in Table 2.

TABLE 2

| | | GS | | | | | | | |
|---|---|---|---|---|---|---|---|---|---|
| | | | | Pitch | | Distance | | | Interlaminar |
| | | | Through | between | Number of | between outer | Rate of | | strength |
| | | Thick- | hole | through | through | diameters of | hole | Corona | (Resistance to |
| | Structure | ness | diameter | holes | holes | through holes | area | treatment | soldering heat) |
| Example 1 | Copper foil/ | 40 | 0.10 | 0.70 | 204 | 0.60 | 1.6 | Not done | D |
| | Glass-epoxy/GS/ | | | | | | | | |
| | Glass-epoxy/ | | | | | | | | |
| | Copper foil | | | | | | | | |
| Example 5 | Copper foil/ | 40 | 0.15 | 0.75 | 178 | 0.60 | 3.1 | Not done | C |
| | Glass-epoxy/GS/ | | | | | | | | |
| | Glass-epoxy/ | | | | | | | | |
| | Copper foil | | | | | | | | |
| Example 6 | Copper foil/ | 40 | 0.20 | 0.80 | 156 | 0.60 | 4.9 | Not done | B |
| | Glass-epoxy/GS/ | | | | | | | | |
| | Glass-epoxy/ | | | | | | | | |
| | Copper foil | | | | | | | | |
| Example 7 | Copper foil/ | 40 | 0.25 | 0.85 | 138 | 0.60 | 6.8 | Not done | B |
| | Glass-epoxy/GS/ | | | | | | | | |
| | Glass-epoxy/ | | | | | | | | |
| | Copper foil | | | | | | | | |
| Comparative | Copper foil/ | 40 | 0.05 | 0.65 | 237 | 0.60 | 0.5 | Not done | E |
| Example 3 | Glass-epoxy/GS/ | | | | | | | | |
| | Glass-epoxy/ | | | | | | | | |
| | Copper foil | | | | | | | | |

As shown in Table 2, comparisons were made under conditions where the distance between outer diameters of through holes was the same. As can be seen from the results shown in Table 2, as in the case of the results shown in Table 1, delamination can be suppressed when the through hole diameter is 0.10 mm or more.

### Example 8

A graphite composite material was produced in the same manner as in Example 1 except that the through holes formed in the graphite film had a diameter of 0.20 mm, and the pitch between the through holes was 1.00 mm (Number of through holes: 100 per cm², Distance between outer diameters of through holes: 0.80 mm, Rate of hole area: 3.1%). The results are shown in Table 3.

### Example 9

A graphite composite material was produced in the same manner as in Example 1 except that the through holes formed in the graphite film had a diameter of 0.20 mm, and the pitch between the through holes was 0.90 mm (Number of through holes: 123 per cm², Distance between outer diameters of through holes: 0.70 mm, Rate of hole area: 3.9%). The results are shown in Table 3.

### Example 10

A graphite composite material was produced in the same manner as in Example 1 except that the through holes formed in the graphite film had a diameter of 0.20 mm, and the pitch between the through holes was 0.60 mm (Number of through holes: 278 per cm², Distance between outer diameters of through holes: 0.40 mm, Rate of hole area: 8.7%). The results are shown in Table 3.

### Example 11

A graphite composite material was produced in the same manner as in Example 1 except that the through holes formed in the graphite film had a diameter of 0.20 mm, and the pitch between the through holes was 0.50 mm (Number of through holes: 400 per cm², Distance between outer diameters of through holes: 0.30 mm, Rate of hole area: 12.6%). The results are shown in Table 3.

### Example 12

A graphite composite material was produced in the same manner as in Example 1 except that the through holes formed in the graphite film had a diameter of 0.20 mm, and the pitch between the through holes was 0.40 mm (Number of through holes: 625 per cm², Distance between outer diameters of through holes: 0.20 mm, Rate of hole area: 19.6%). The results are shown in Table 3.

### Comparative Example 4

A graphite composite material was produced in the same manner as in Example 1 except that the through holes formed in the graphite film had a diameter of 0.20 mm, and the pitch between the through holes was 1.10 mm (Number of through holes: 83 per cm², Distance between outer diameters of through holes: 0.90 mm, Rate of hole area: 2.6%). The results are shown in Table 3.

TABLE 3

| | | GS | | | | | | | |
|---|---|---|---|---|---|---|---|---|---|
| | | | | Pitch | | Distance | | | Interlaminar |
| | | | Through | between | Number of | between outer | Rate of | | strength |
| | | Thick- | hole | through | through | diameters of | hole | Corona | (Resistance to |
| | Structure | ness | diameter | holes | holes | through holes | area | treatment | soldering heat) |
| Example 8 | Copper foil/ | 40 | 0.20 | 1.00 | 100 | 0.80 | 3.1 | Not done | D |
| | Glass-epoxy/GS/ | | | | | | | | |
| | Glass-epoxy/ | | | | | | | | |
| | Copper foil | | | | | | | | |
| Example 9 | Copper foil/ | 40 | 0.20 | 0.90 | 123 | 0.70 | 3.9 | Not done | C |
| | Glass-epoxy/GS/ | | | | | | | | |
| | Glass-epoxy/ | | | | | | | | |
| | Copper foil | | | | | | | | |
| Example 3 | Copper foil/ | 40 | 0.20 | 0.70 | 204 | 0.50 | 6.4 | Not done | B |
| | Glass-epoxy/GS/ | | | | | | | | |
| | Glass-epoxy/ | | | | | | | | |
| | Copper foil | | | | | | | | |
| Example 10 | Copper foil/ | 40 | 0.20 | 0.60 | 278 | 0.40 | 8.7 | Not done | A |
| | Glass-epoxy/GS/ | | | | | | | | |
| | Glass-epoxy/ | | | | | | | | |
| | Copper foil | | | | | | | | |
| Example 11 | Copper foil/ | 40 | 0.20 | 0.50 | 400 | 0.30 | 12.6 | Not done | A |
| | Glass-epoxy/GS/ | | | | | | | | |
| | Glass-epoxy/ | | | | | | | | |
| | Copper foil | | | | | | | | |
| Example 12 | Copper foil/ | 40 | 0.20 | 0.40 | 625 | 0.20 | 19.6 | Not done | A |
| | Glass-epoxy/GS/ | | | | | | | | |
| | Glass-epoxy/ | | | | | | | | |
| | Copper foil | | | | | | | | |
| Comparative | Copper foil/ | 40 | 0.20 | 1.10 | 83 | 0.90 | 2.6 | Not done | E |
| Example 4 | Glass-epoxy/GS/ | | | | | | | | |
| | Glass-epoxy/ | | | | | | | | |
| | Copper foil | | | | | | | | |

As shown in Table 3, comparisons were made under conditions where the through hole diameter was the same (0.20 mm). In the case of Comparative Example 4 in which the number of through holes was as small as 83 per cm², significant delamination occurred. This is because when the number of through holes is as small as 83 per cm², gaps between the through holes are wide, and therefore delamination is likely to occur in areas between the through holes. On the other hand, as can be seen from the results of Examples 8 to 12, delamination in areas between the through holes is also suppressed when the number of through holes is 100 per cm² or more. Further, as can be seen from the results of Examples 8 to 12, the effect of suppressing delamination is higher when the number of through holes is larger. In the cases of Examples 10 and 11 in which the number of through holes was 278/cm² or more, delamination did not occur.

### Example 13

A graphite composite material was produced in the same manner as in Example 3 except that after the through holes were formed in the graphite film, both surfaces of the graphite film were subjected to corona discharge treatment at a corona discharge density of 3000 W-min/m² using Corona Master PS-10S available from SHINKO ELECTRIC & INSTRUMENTATION CO., LTD. The results are shown in Table 4.

TABLE 4

| | | GS | | | | | | | |
|---|---|---|---|---|---|---|---|---|---|
| | | | | Pitch | | Distance | | | |
| | | | Through | between | Number of | between outer | Rate of | | Interlaminar |
| | | Thick- | hole | through | through | diameters of | hole | | strength |
| | | ness | diameter | holes | holes | through holes | area | Corona | (Resistance to |
| | Structure | μm | mm | mm | per cm² | mm | % | treatment | soldering heat) |
| Example 3 | Copper foil/ | 40 | 0.20 | 0.70 | 204 | 0.50 | 6.4 | Not done | B |
| | Glass-epoxy/GS/ | | | | | | | | |
| | Glass-epoxy/ | | | | | | | | |
| | Copper foil | | | | | | | | |
| Example 13 | Copper foil/ | 40 | 0.20 | 0.70 | 204 | 0.50 | 6.4 | Done | A |
| | Glass-epoxy/GS/ | | | | | | | | |
| | Glass-epoxy/ | | | | | | | | |
| | Copper foil | | | | | | | | |

Performing corona discharge treatment in addition to forming through holes in the graphite film makes it possible to suppress delamination also in areas between the through holes where delamination is likely to occur. Therefore, delamination was more suppressed in Example 13 in which corona discharge treatment was performed than in Example 3 in which corona discharge treatment was not performed.

### Example 14

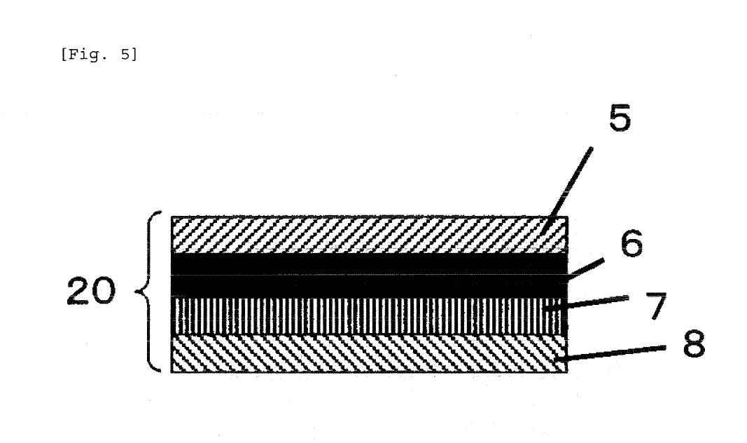

Through holes were formed by cutting out circles in the graphite film (thickness: 40 μm) with Laser Marker MD-T1010 manufactured by KEYENCE CORPORATION at a laser wavelength of 532 nm, a laser power of 80%, a frequency of 50 kHz, and a rate of 50 mm/min. Then, graphite powder created by laser processing was removed in an ultrasonic bath. The through holes had a diameter of 0.20 mm, and the pitch between the through holes was 0.70 mm (Number of through holes: 204 per cm², Distance between outer diameters of through holes: 0.50 mm, Rate of hole area: 6.4%). After the through holes were formed in the graphite film, both surfaces of the graphite film were subjected to corona discharge treatment at a corona discharge density of 3000 W-min/m² using Corona Master PS-10S available from SHINKO ELECTRIC & INSTRUMENTATION CO., LTD. Then, as shown in FIG. 5, the graphite film 6 (40 μm), a coverlay 5 (CISV-1225 (epoxy resin: 25 μm, polyimide film (PI): 12.5 μm) manufactured by NIKKAN INDUSTRIES Co., Ltd.), a copper-coated polyimide film 8 (R-F770 (copper foil: 35 μm, polyimide film (PI): 25 μm) manufactured by Panasonic Corporation), and a bonding sheet 7 (AY-25KA (epoxy resin: 25 μm) manufactured by Arisawa Manufacturing Co., Ltd.) were stacked to obtain a layered structure. Then, this layered structure was hot-pressed to produce a graphite composite material 20. The hot pressing was performed to cure the resin in the following manner: buffer materials were placed on both surfaces of the layered structure, and the layered structure was preheated at 100° C. and 3.0 MPa for 10 minutes and then heated to 160° C. and maintained at 160° C. and 3.0 MPa for 1 hour. In this way, a graphite composite material 20 in which a resin layer was formed also in the through holes was produced. The results are shown in Table 5.

### Example 15

A graphite composite material was produced in the same manner as in Example 14 except that the through holes formed in the graphite film had a diameter of 0.20 mm, and the pitch between the through holes was 0.50 mm (Number of through holes: 400 per cm², Distance between outer diameters of through holes: 0.30 mm, Rate of hole area: 12.6%). The results are shown in Table 5.

### Comparative Example 5

A graphite composite material was produced in the same manner as in Example 14 except that through holes were not formed in the graphite film. The results are shown in Table 5.

TABLE 5

| | | GS | | | | | | | |
|---|---|---|---|---|---|---|---|---|---|
| | | | | Pitch | | Distance | | | |
| | | | Through | between | Number of | between outer | Rate of | | Interlaminar |
| | | Thick- | hole | through | through | diameters of | hole | | strength |
| | | ness | diameter | holes | holes | through holes | area | Corona | (Resistance to |
| | Structure | μm | mm | mm | per cm² | mm | % | treatment | soldering heat) |
| Example 14 | Copper foil/ | 40 | 0.20 | 0.75 | 204 | 0.50 | 6.4 | Done | C |
| | PI/Epoxy/GS/ | | | | | | | | |
| | Epoxy/PI | | | | | | | | |
| Example 15 | Copper foil/ | 40 | 0.20 | 0.50 | 400 | 0.30 | 12.6 | Done | B |
| | PI/Epoxy/GS/ | | | | | | | | |
| | Epoxy/PI | | | | | | | | |
| Comparative | Copper foil/ | 40 | — | — | 0 | — | 0.0 | Done | E |
| Example 5 | PI/Epoxy/GS/ | | | | | | | | |
| | Epoxy/PI | | | | | | | | |

### Example 16

A graphite composite material was produced in the same manner as in Example 14 except that the through holes formed in the graphite film had a diameter of 0.10 mm, and the pitch between the through holes was 0.35 mm (Number of through holes: 816 per cm², Distance between outer diameters of through holes: 0.25 mm, Rate of hole area: 6.4%). The results are shown in Table 6.

### Example 17

A graphite composite material was produced in the same manner as in Example 14 except that the through holes formed in the graphite film had a diameter of 0.15 mm, and the pitch between the through holes was 0.45 mm (Number of through holes: 494 per cm², Distance between outer diameters of through holes: 0.30 mm, Rate of hole area: 8.7%). The results are shown in Table 6.

### Example 18

A graphite composite material was produced in the same manner as in Example 14 except that the through holes formed in the graphite film had a diameter of 0.20 mm, and the pitch between the through holes was 0.60 mm (Number of through holes: 278 per cm², Distance between outer diameters of through holes: 0.40 mm, Rate of hole area: 8.7%). The results are shown in Table 6.

TABLE 6

| | | GS | | | | | | | | |
|---|---|---|---|---|---|---|---|---|---|---|
| | | | | Pitch | | Distance | | | | |
| | | | Through | between | Number of | between outer | Rate of | | | |
| | | Thick- | hole | through | through | diameters of | hole | | | Peel |
| | | ness | diameter | holes | holes | through holes | area | Corona | Resistance to | strength |
| | Structure | μm | mm | mm | per cm² | mm | % | treatment | soldering heat | N/mm |
| Example 16 | Copper foil/ | 40 | 0.10 | 0.35 | 816 | 0.25 | 6.4 | Done | D | 0.15 |
| | PI/Epoxy/GS/ | | | | | | | | | |
| | Epoxy/PI | | | | | | | | | |
| Example 17 | Copper foil/ | 40 | 0.15 | 0.45 | 494 | 0.30 | 8.7 | Done | C | 0.21 |
| | PI/Epoxy/GS/ | | | | | | | | | |
| | Epoxy/PI | | | | | | | | | |
| Example 18 | Copper foil/ | 40 | 0.20 | 0.60 | 278 | 0.40 | 8.7 | Done | B | 0.36 |
| | PI/Epoxy/GS/ | | | | | | | | | |
| | Epoxy/PI | | | | | | | | | |
| Comparative | Copper foil/ | 40 | — | — | 0 | — | 0.0 | Done | E | 0.02 |
| Example 5 | PI/Epoxy/GS/ | | | | | | | | | |
| | Epoxy/PI | | | | | | | | | |

In the case of Comparative Example 5 in which through holes were not formed in the graphite film and significant delamination occurred in the test for resistance to soldering heat, the peel Strength was 0.02 N/mm. On the other hand, in the cases of Examples 16 to 18 in which delamination was improved in the test for resistance to soldering heat, the peel strength was also improved to 0.15 N/mm or more. Further, as can be seen from a comparison among Examples 16 to 18, the peel strength is improved when the resistance to soldering heat is improved.

### REFERENCE SIGNS LIST

1 Through hole
2 Pitch between through holes
3 Distance between outer diameters of through holes
4 Through hole diameter

### 5 Coverlay

6 Graphite film
7 Bonding sheet
8 Copper-coated polyimide film
9 Double-sided tape
10 ABS plate
20 Graphite composite material
31 Glass-epoxy prepreg
32 Copper foil

1. A graphite composite material comprising: a graphite film; and resin layers formed on both surfaces of the graphite film, wherein the graphite film has through holes, wherein a number of the through holes is 100 to 1000 per cm², and the through holes have a diameter of 0.10 mm or more but 1.00 mm or less, and wherein part of the resin layer is formed also in the through holes.

2. The graphite composite material according to claim 1, which has an interlaminar strength of 0.15 N/mm or more.

3. The graphite composite material according to claim 1, wherein a distance between outer diameters of the through holes is 0.80 mm or less.

4. The graphite composite material according to claim 1, wherein the graphite film has been subjected to at least one film surface treatment selected from the group consisting of corona treatment, flame treatment, ultraviolet treatment, alkali treatment, primer treatment, sandblast treatment, and plasma treatment.

5. A circuit board comprising the graphite composite material according to any one of claims 1 to 4.
